(19) United States
(12) Patent Application Publication
(10) Pub. No.: US 2008/0185738 A1
(43) Pub. Date: Aug. 7, 2008

(54) SEMICONDUCTOR DEVICE AND METHOD OF MANUFACTURING THE SAME

(75) Inventors: Jae Sik CHUNG, Kyungi-do (KR); Sung Min SIM, Kyungi-do (KR); Hee Kook CHOI, Seoul (KR); Dong Hyeon JANG, Kyunggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/016,677

(22) Filed: Jan. 18, 2008

(30) Foreign Application Priority Data
Feb. 1, 2007 (KR) 2007-0010377

(51) Int. Cl. H01L 23/52; H01L 21/44

(52) U.S. Cl. 257/782; 438/612; 257/E23.141; 257/E21.476

(57) ABSTRACT

A semiconductor device and a method for fabricating the same are disclosed. According to some embodiments, a semiconductor device comprises a lower structure formed on a semiconductor structure. The lower structure has chip pads. The semiconductor device further comprises a passivation layer located over the chip pads. The passivation layer comprises first openings defined therein to expose at least a portion of the chip pads. The semiconductor device additionally includes at least two adjacent redistribution lines spaced apart from each other and located over the passivation layer. The at least two redistribution lines are respectively coupled to the chip pads through corresponding ones of the first openings. The semiconductor device comprises a first insulation layer located over the passivation layer. The first insulation layer includes a void extending between the at least two adjacent redistribution lines.

This application claims priority from Korean Patent Application No. 2007-0010377, filed on Feb. 1, 2007, the contents of which are incorporated herein by reference in their entirety.

### BACKGROUND

1. Field of Invention

Embodiments of the present invention generally relate to semiconductor devices and methods of fabricating the same. More particularly, some embodiments of the present invention relate to a semiconductor device incorporating redistribution lines adapted to reduce parasitic capacitance between adjacent redistribution lines and a method of fabricating the same.

2. Description of the Related Art

In modern semiconductor device manufacturing, it is often required that bonding pads of semiconductor chips that are to be assembled in different package types be rearranged to accommodate the different package types. However, it is not cost efficient to modify the entire distribution of electrical components of a semiconductor chip simply to rearrange bonding pads when there is substantially no change in the functionality of the semiconductor chip.

Therefore, redistribution lines have been proposed as an efficient means of rearranging bonding pads to accommodate different package types without modifying the distribution of electrical components. Typical redistribution lines can be characterized as a conductive interconnect disposed over a passivation layer of a completed semiconductor chip. For example, existing chip pads formed at peripheral regions of the completed semiconductor chip can be electrically connected (redistributed) to an array of redistributed bond pads via the redistribution lines as explained further below.

FIG. 1 is a cross-sectional view of a conventional wafer level package including a redistribution line.

Referring to FIG. 1, a semiconductor chip includes a semiconductor substrate 10, a chip pad 12, a passivation layer 14 disposed over the chip pad 12 and a first insulation layer 16 disposed over the passivation layer 14. Openings are defined through the passivation layer 14 and the first insulation layer 16 to expose a portion of the chip pad 12.

A redistribution line or redistribution layer pattern 18 is formed on the first insulation layer 16 so as to contact the portion of the chip pad 12 exposed by the openings formed in the passivation layer 14 and the first insulation layer 16.

A second insulation layer 20 is then formed over the redistribution line 18 and an opening is formed within the second insulation layer 20 to expose a portion of the redistribution line 18 to define a redistributed bond pad 22. A solder ball 24 is then formed so as to contact the portion of the redistributed bond pad 22. The opening may be formed in the second insulation layer 20 at any region over the semiconductor substrate 10.

Accordingly, by applying redistribution technology, the chip pads 12 located in peripheral regions of the chip can be electrically relocated to the redistributed bond pads 22 located over any region of the chip via a redistribution line. Thus, peripheral bonding pads can be changed to area array bonding pads that are suitable for assembly techniques such as flip chip bonding, and vice versa.

However, as the level of integration within semiconductor chips increases, the distance between adjacent redistribution lines substantially decreases. As a result, the parasitic capacitance generated between adjacent redistribution lines undesirably increases, which results in significant signal delay and more power consumption. Also, it has been known in the art that such parasitic capacitance in various semiconductor devices such as a flash memory leads to signal interference, lowering the reliability of the resulting electronic products.

Embodiments of the present invention, exemplarily described herein, address these and other observed disadvantages of the conventional art.

### SUMMARY

In one embodiment, a semiconductor device comprises: a lower structure formed on a semiconductor structure, the lower structure having chip pads; a passivation layer located over the chip pads, the passivation layer comprising first openings defined therein to expose at least a portion of the chip pads; at least two adjacent redistribution lines spaced apart from each other and located over the passivation layer, the at least two redistribution lines respectively coupled to the chip pads through corresponding ones of the first openings; and a first insulation layer located over the passivation layer. The first insulation layer includes a void extending between the at least two adjacent redistribution lines.

### BRIEF DESCRIPTION OF THE DRAWINGS

Hereinafter, embodiments of the present invention will be described with reference to the accompanying drawings, in which:

FIG. 1 is a cross-sectional view of a conventional wafer level fabricated package including a redistribution line;

FIG. 2 is a plan view of a semiconductor device according to one embodiment;

FIG. 3A is a cross-sectional view of the semiconductor device shown in FIG. 2, taken along line IIA-IIA′, according to one embodiment;

FIGS. 3B and 3C are cross-sectional views of the semiconductor device shown in FIG. 2, taken along line IIB-IIB′, according to some embodiments;

FIG. 3D is a diagram illustrating the formation of voids in accordance with an embodiment of the present invention;

FIG. 4 is a plan view of a semiconductor device according to another embodiment;

FIGS. 5A and 5B are cross-sectional views of the semiconductor device shown in FIG. 4, taken along lines IVA-IVA′ and IVB-IVB′, respectively;

FIG. 6 is a plan view of a semiconductor device according to yet another embodiment;

FIG. 7A is a cross-sectional view of the semiconductor device shown in FIG. 6, taken along line VIA-VIA′, according to one embodiment;

FIGS. 7B through 7D are cross-sectional views of the semiconductor device shown in FIG. 6, taken along line VIB-VIB′, according to some embodiments;

FIGS. 8A, 9A, 10A, 11A, 12A and 13A are cross-sectional views of an exemplary method of forming one embodiment of the semiconductor device shown in FIG. 2, taken along lines IIA-IIA′;

FIGS. 8B, 9B, 10B, 11B, 12B and 13B are cross-sectional views of an exemplary method of forming one embodiment of the semiconductor device shown in FIG. 2, taken along lines IIB-IIB′;

FIG. 14A is a cross-sectional view of an exemplary method of forming one embodiment of the semiconductor device shown in FIG. 4, taken along lines IVA-IVA′;

FIG. 14B is a cross-sectional view of an exemplary method of forming one embodiment of the semiconductor device shown in FIG. 4, taken along lines IVB-IVB′;

FIGS. 15A, 16A and 17A are cross-sectional views of an exemplary method of forming one embodiment of the semiconductor device shown in FIG. 6, taken along lines VIA-VIA′;

FIGS. 15B, 16B and 17B are cross-sectional views of an exemplary method of forming one embodiment of the semiconductor device shown in FIG. 6, taken along lines VIB-VIB′; and

FIGS. 18 to 20 illustrate exemplary implementations of the semiconductor devices shown in FIGS. 2, 4 and 6, according to some embodiments.

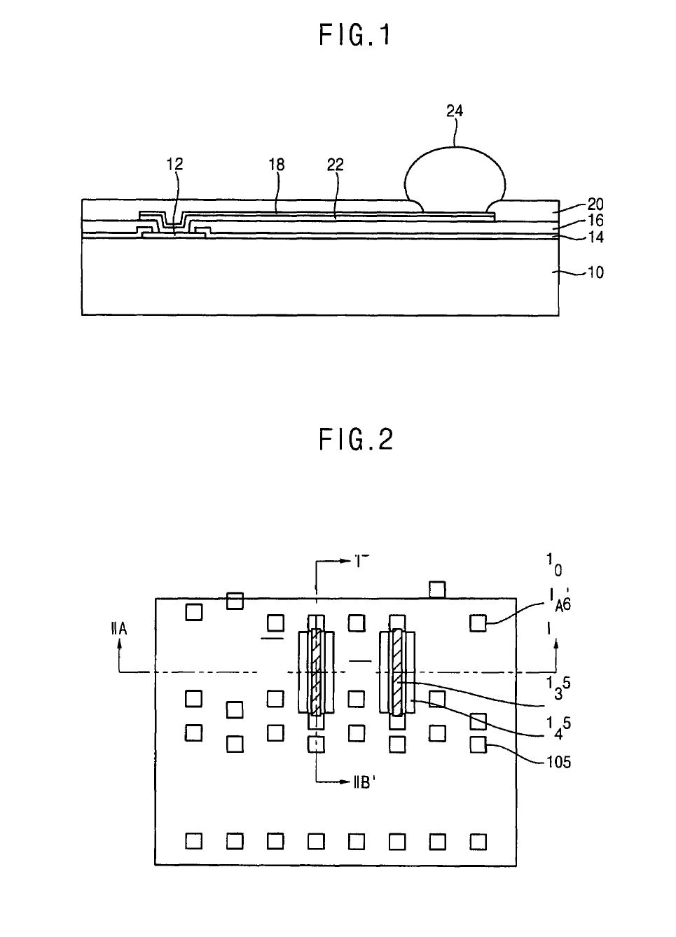

### DETAILED DESCRIPTION

Exemplary embodiments of the present invention will now be described more fully hereinafter with reference to the accompanying drawings. These embodiments may, however, be realized in many different forms and should not be construed as being limited to the embodiments set forth herein. Rather, these embodiments are provided so that this disclosure will be thorough and complete, and will fully convey the scope of the invention defined in the claims to those skilled in the art. In the drawings, the thicknesses of layers and regions are exaggerated for clarity. Like numbers refer to like elements throughout the specification.

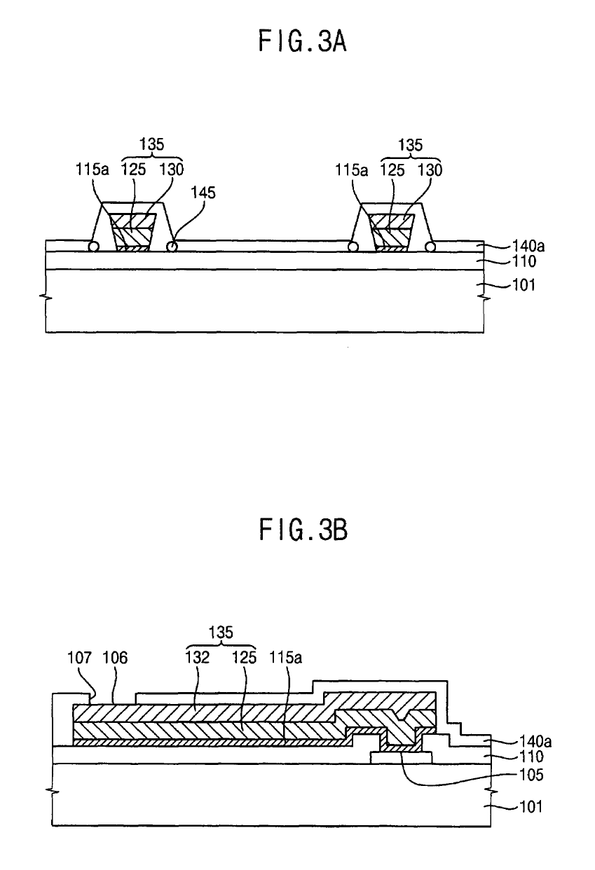

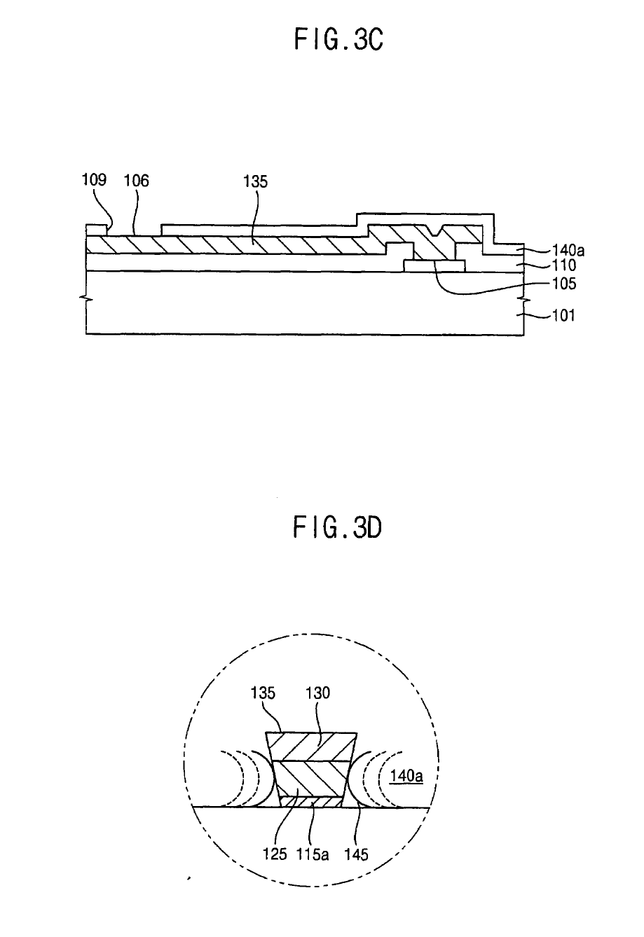

FIG. 2 is a plan view of a semiconductor device according to one embodiment. FIG. 3A is a cross-sectional view of the semiconductor device shown in FIG. 2, taken along line IIA-IIA′, according to one embodiment. FIGS. 3B and 3C are cross-sectional views of the semiconductor device shown in FIG. 2, taken along line IIB-IIB′, according to some embodiments.

Referring to FIGS. 2 and 3A to 3C, a semiconductor device may, for example, include a lower structure 101 having a plurality of chip pads 105, a passivation layer 110 located over the lower structure 101 having the plurality of chip pads 105, one or more redistribution lines 135 (also referred to as “first redistribution lines”) over the passivation layer 110, an insulation layer 140a (also referred to herein as a “first insulation layer”) over the one or more redistribution lines 135, one or more voids 145 over the passivation layer 110 and a plurality of redistributed bond pads 106. Although only two first redistribution lines 135 are shown, it will be appreciated that any number of first redistribution lines 135 may be provided. In some embodiments, the one or more voids 145 are disposed over the passivation layer and/or between the redistribution lines 135.

The semiconductor device discussed above with reference to FIGS. 2 and 3A to 3C is hereby described in further detail as shown below. In particular, the lower structure 101 may, for example, include one or more devices such as transistors, resistors, diode, capacitors, signal lines, contact structures and so on. The passivation layer 110 may be located over the lower structure 101 and have openings therein to define the plurality of chip pads 105. The chip pads 105 are formed of a conductive material such as aluminum, copper, tungsten, titanium, etc. as is known to one skilled in the art.

In the present application, the passivation layer 110 is a conventional passivation layer which has an opening to define bond pads or chip pads of a completed chip to be connected (redistributed) to redistributed bond pads via redistribution lines. Therefore, even without the redistributed bond pads, the completed chip may fully function as a semiconductor device such as a dynamic random access memory (DRAM) or a flash memory and can be assembled to form a semiconductor package.

In one aspect, the first redistribution lines 135 may be provided as power paths, ground paths, input/output (I/O) paths, or the like or a combination thereof. Also, the shape of the first redistribution lines 135 is shown to be a straight bar shape. However, other suitable shapes such as a serpentine shape may be used within the spirit and scope of the present invention.

In another aspect, the first redistribution line 135 may be coupled to a chip pad 105 through a first opening defined in the passivation layer 110. In still another aspect although not shown in FIG. 3C, a first conductive interlayer pattern 115a may be provided between the passivation layer 110 and the first redistribution line 135. The first conductive interlayer pattern 115a may include a seed layer as will be explained further below.

In one embodiment, and as exemplarily shown in FIGS. 3A and 3B, each first redistribution line 135 may, for example, include a first lower conductive layer 125 and a first upper conductive layer 130, which are sequentially stacked. In another embodiment exemplarily shown in FIG. 3C, however, the first redistribution line 135 may be provided as a single layer of conductive material. It will be appreciated that the first redistribution line 135 may be provided with any number of layers of conductive material. Also, the first conductive interlayer 115a may also be provided with any number of layers of conductive material including copper and titanium.

In the embodiment exemplarily shown in FIG. 3A, an upper portion of the first redistribution line 135 may be formed wider than a lower portion of the first redistribution line 135 using a mold pattern as described below or known etching techniques. In another embodiment, at least a portion of the sidewall of the first redistribution line 135 may define an acute angle (i.e., an angle less than 90°) with the upper surface of the passivation layer 110 as shown in FIG. 3A. However, it is not necessary that the acute angle be formed by the sidewall of the first redistribution line 135 and the upper surface of the passivation layer 110. In some other embodiments, obtuse angles or a right angle may be formed by a portion of the sidewall of the first redistribution line 135 and the upper surface of the passivation layer 110.

In yet another embodiment, a recess or undercut may be defined in a sidewall of the first redistribution lines 135. For example, the recess may be defined in a sidewall of the lower portion of the first redistribution lines 135. The recess may be formed when the sidewall of the first redistribution line 135 forms an acute angle (i.e., an angle less than 90°) with the upper surface of the passivation layer 110 as illustrated in FIG. 3. On the other hand, although not shown, a recess or undercut may be formed by selectively removing a portion of the first redistribution line 135 as described further below.

In one embodiment, the first insulation layer 140a may be located over the passivation layer 110 and also be located adjacent to the sidewall of the first redistribution line 135. In the embodiment exemplarily shown in FIG. 3A, a top surface of the first insulation layer 140a, where the first redistribution line 135 is not formed, may be lower than a top surface of the first redistribution line 135. In another embodiment, the top surface of the first insulation layer 140a, where the first redistribution line 135 is not formed, may be higher than or substantially planar with the top surface of the first redistribution line 135.

As exemplarily shown in FIG. 3B, a plurality of openings 107 (also referred to herein as “second openings”) may be formed in the first insulation layer 140a to expose at least a portion of a first redistribution line 135. The portion of the first redistribution line 135 exposed by the second opening 107 may be referred to herein as a redistributed bond pad 106.

In one embodiment, the one or more voids 145 may be formed in the first insulation layer 140a. The one or more voids 145 may be adjacent to sidewalls of the first redistribution lines 135. The one or more voids 145 may be located over the passivation layer 110. In one embodiment, and as exemplarily shown in FIGS. 2 and 3A, the one or more voids 145 are present between adjacent ones of the first redistribution lines 135. In the embodiment exemplarily shown in FIGS. 2 and 3A, the one or more voids 145 may be spaced apart from sidewalls of the adjacent ones of the first redistribution lines 135 by the first insulation layer 140a. In another embodiment, however, the voids 145 may contact sidewalls of the first redistribution lines 135 such that at least a portion of the sidewalls of the adjacent ones of the first redistribution lines 135 are exposed to the interior of the voids 145. In other words, the voids 145 may be defined by an outer surface of the first insulation layer 140a and the sidewall of the first redistribution lines 135 as illustrated in FIG. 3D. In the embodiment exemplarily shown in FIG. 2, at least some of the voids 145 may extend along the length of one of the plurality of first redistribution lines 135.

As described above, the recess may be defined in a sidewall of the first redistribution line 135. For example, the recess may be defined in the sidewall of the lower portion of the first redistribution line 135. In such an embodiment, at least a portion of the void 145 may be formed within the recess.

According to the semiconductor device exemplarily described with respect to FIGS. 2, 3A and 3B, the voids 145 are present between adjacent ones of the plurality of first redistribution lines 135 that are formed on the passivation layer 110. In one embodiment, the voids 145 are filled with air. The dielectric constant of air, εₐᵢᵣ, is about 1 whereas the dielectric constant of the first insulation layer 140a, ε_{ILD}, is typically greater than 2. The capacitance, C, of a system can generally be represented by the following formula: C=ε(A/d), where ε is the dielectric constant of a material between two conductive structures, A is the area of the conductive structures and d is the distance between the two conductive structures. Accordingly, the voids 145 may reduce a parasitic capacitance that would otherwise be generated between adjacent ones of the plurality of first redistribution lines 135 formed on the passivation layer 110.

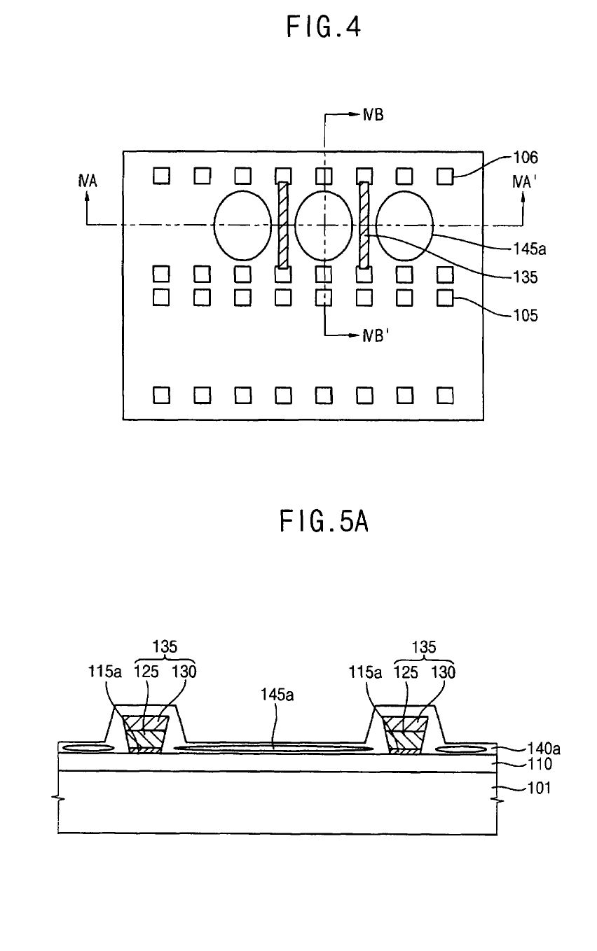

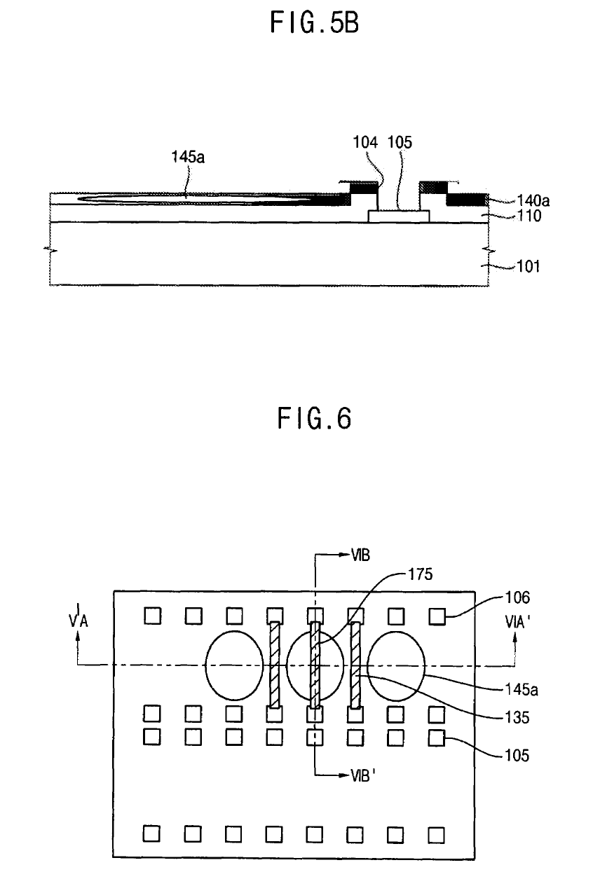

FIG. 4 is a plan view of a semiconductor device according to another embodiment. FIGS. 5A and 5B are cross-sectional views of the semiconductor device shown in FIG. 4, taken along lines IVA-IVA′ and IVB-IVB′, respectively.

Referring to FIGS. 4, 5A and 5B, a semiconductor device may, for example, have a similar configuration as described with respect to FIGS. 2 and 3A to 3C. In the embodiment exemplarily illustrated in FIGS. 4, 5A and 5B, however, an enlarged void 145a may be present between adjacent ones of first redistribution lines 135 formed on the passivation layer 110. In such an embodiment, the enlarged void 145a extends between adjacent ones of first redistribution lines 135 and overlies the passivation layer 110.

In one embodiment, the enlarged void 145a may be spaced apart from a sidewall of one or both of the adjacent ones of the first redistribution lines 135. The enlarged void 145a may have an oval shape in plan view. However, the enlarged void 145a is not limited to this shape and other suitable shapes such as a substantially rectangle shape or an arch shape in cross section view within the spirit and scope of the present invention may also be used.

In another embodiment, however, the enlarged void 145a may contact a sidewall of one or both of the adjacent ones of the first redistribution lines 135 such that at least a portion of a sidewall of one or both of the adjacent ones of the first redistribution lines 135 is exposed to the interior of the enlarged void 145a. Although only one enlarged void 145a is shown as being present between adjacent ones of the first redistribution lines 135, it will be appreciated that a plurality of enlarged voids 145a may be present between adjacent ones of the first redistribution lines 135.

As discussed, the semiconductor device exemplarily described with respect to FIGS. 4, 5A and 5B may include at least one enlarged void 145a present between adjacent ones of the first redistribution lines 135 formed on the passivation layer 110. Because the enlarged void 145a can be filled with air, the enlarged voids 145a may reduce a parasitic capacitance that would otherwise be generated, for example, between adjacent ones of the first redistribution lines 135 formed on the passivation layer 110.

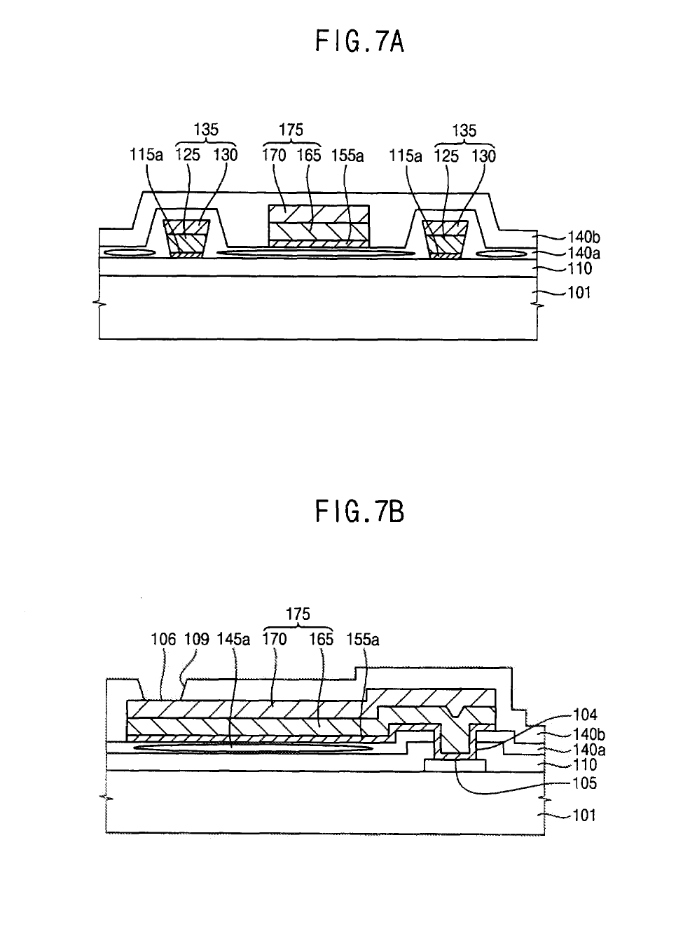

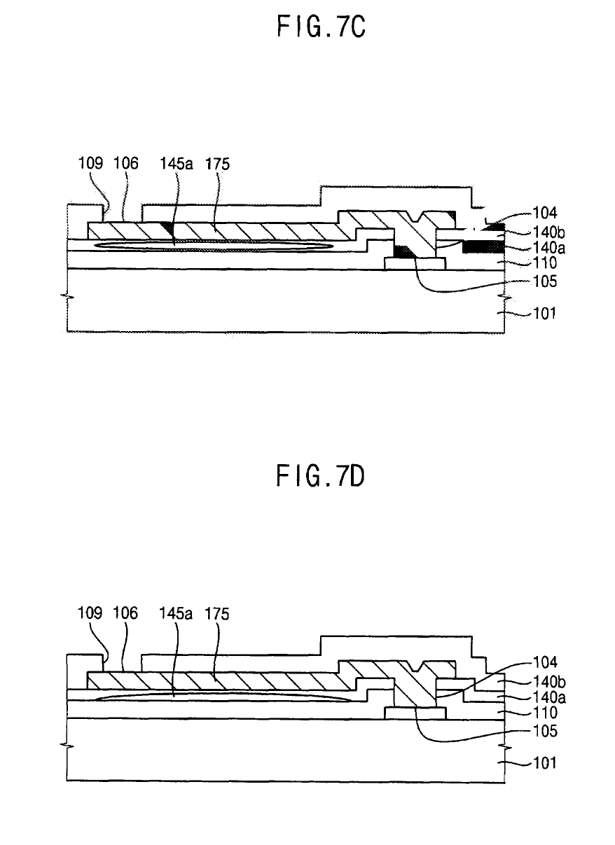

FIG. 6 is a plan view of a semiconductor device according to yet another embodiment. FIG. 7A is a cross-sectional view of the semiconductor device shown in FIG. 6, taken along line VIA-VIA′, according to one embodiment. FIGS. 7B and 7C are cross-sectional views of the semiconductor device shown in FIG. 6, taken along line VIB-VIB′, according to some embodiments.

Referring to FIGS. 6 and 7A to 7C, a semiconductor device may, for example, have a similar configuration as described with respect to FIGS. 4, 5A and 5B. In the embodiment exemplarily illustrated in FIGS. 6 and 7A to 7C, however, the semiconductor device may further include another redistribution line 175 (also referred to herein as a “second redistribution line) and another insulation layer 140b (also referred to herein as a “second insulation layer). Although only one second redistribution line 175 is shown, it will be appreciated that more than one second redistribution line 175 may be provided.

In one embodiment, the passivation layer 110 may be disposed over the lower structure 101 having the chip pads 105 formed thereon, as described above. One or more first redistribution lines 135 and a first insulation layer 140a are also formed using the methods described above or similar methods. Openings (also referred to herein as “first openings”) may be defined within the passivation layer 110 and the first insulation layer 140a. In one embodiment, a first opening 104 defined through the passivation layer 110 and the first insulation layer 140a may expose at least a portion of a chip pad 105.

In one embodiment, the second redistribution line 175 is located over an enlarged void 145a between adjacent ones of the first redistribution lines 135. Although only one second redistribution line 175 is illustrated, it will be appreciated that a plurality of second redistribution lines 175 may be provided such that a plurality of second redistribution lines 175 are located over different ones of the enlarged voids 145a, such that a plurality of second redistribution lines 175 are located over the same enlarged void 145a, or a combination thereof.

In another embodiment, a second conductive interlayer pattern 155a as a seed layer may be provided between the first insulation layer 140a and the second redistribution line 175 if a plating process is used to form the second redistribution line 175. The second conductive interlayer pattern 155a may be formed of a conductive material such as aluminum, copper, tungsten or titanium as is known to one skilled in the art. The second conductive interlayer pattern 155a may be a single layer or a multi-layer pattern depending on specific applications, although not shown FIG. 7C. For example, the second conductive interlayer pattern 155a may include a copper layer pattern and a titanium layer pattern formed on the copper layer pattern.

In one embodiment, and as exemplarily shown in FIGS. 7A and 7B, each second redistribution line 175 may, for example, include a second lower conductive layer 165 and a second upper conductive layer 170, which are sequentially stacked. In another embodiment exemplarily shown in FIG. 7C, however, the second redistribution line 175 may be provided as a single layer of conductive material. It will be appreciated, however, that the second redistribution line 175 may be provided with any number of layers of conductive material. In one aspect, the second redistribution line 175 may be provided as a power path, ground path, input/output (I/O) path, or the like or a combination thereof. In another aspect, the second redistribution line 175 may be coupled to a chip pad 105 through the first opening 104 extending through the passivation layer 110 and the first insulation layer 140a.

In one embodiment, the second insulation layer 140b is located over the first insulation layer 140a. The second insulation layer 140b may also be located over the second redistribution line 175. As exemplarily shown in FIG. 7B, another opening 109 (also referred to herein as a “third opening”) may be formed within the second insulation layer 140b to expose at least a portion of the second redistribution line 175. The portion of the second redistribution line 175 exposed by the third opening 109 may be referred to as a redistributed bond pad 106.

Similar to the semiconductor devices exemplarily described with respect to FIGS. 4, 5A and 5B, the semiconductor device exemplarily described with respect to FIGS. 6 and 7A to 7C may include an enlarged void 145a present between adjacent ones of the first redistribution lines 135 formed on the passivation layer 110. Because the enlarged void 145a can be filled with air, the enlarged voids 145a may reduce a parasitic capacitance that would otherwise be generated along the horizontal direction between adjacent ones of the first redistribution lines 135 formed on the passivation layer 110. Furthermore, because the second redistribution line 175 is provided over the enlarged void 145a, a parasitic capacitance that would otherwise be generated between adjacent ones of the first and second redistribution lines 135 and 175 can be reduced. Further, the parasitic capacitance that would otherwise be generated between the lower structure 101 and the second redistribution line 135 along the vertical direction can be reduced.

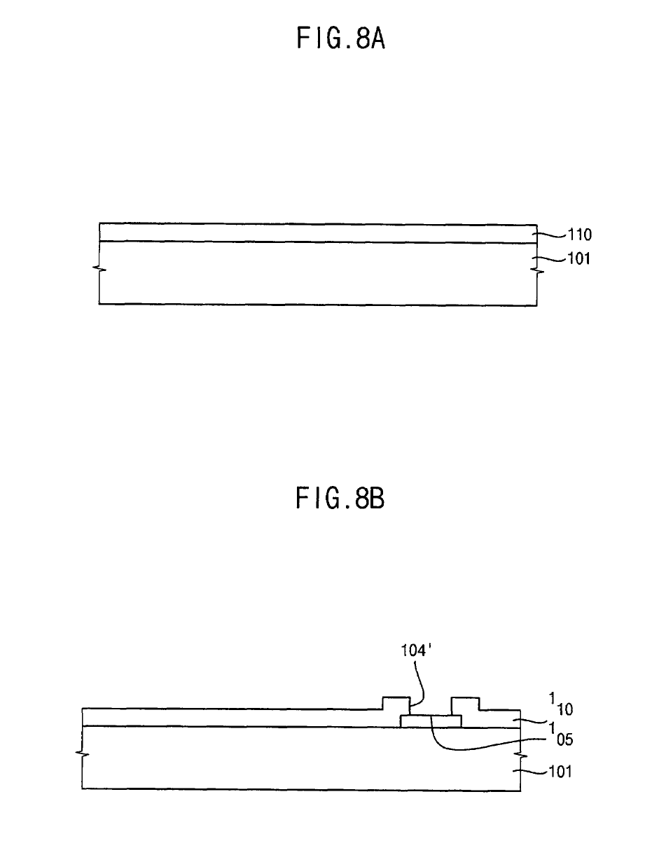

Having exemplarily described semiconductor devices according to some embodiments of the present invention, exemplary methods of forming the semiconductor devices described with respect to FIGS. 2 to 7C will be described with reference to FIGS. 8A to 17B.

FIGS. 8A, 9A, 10A, 11A, 12A and 13A are cross-sectional views of an exemplary method of forming one embodiment of the semiconductor device shown in FIG. 2, taken along lines IIA-IIA′. FIGS. 8B, 9B, 10B, 11B, 12B and 13B are cross-sectional views of an exemplary method of forming one embodiment of the semiconductor device shown in FIG. 2, taken along lines IIB-IIB′.

Referring to FIGS. 8A and 8B, a passivation layer 110 is formed over a lower structure 101 having a chip pad 105 already formed thereon. In one embodiment, the passivation layer 110 may be formed by depositing a passivation material such as, for example, SiNₓ, SiOₓ, or the like or a combination thereof over the lower structure 101 and patterning the passivation material to form an opening (i.e., a first opening 104′) to expose at least a portion of the chip pad 105 using conventional techniques such as a photolithography process. Although only one first opening 104′ and one chip pad 105 are shown, it will be appreciated that any number of first openings 104′ and chip pads 105 may be formed.

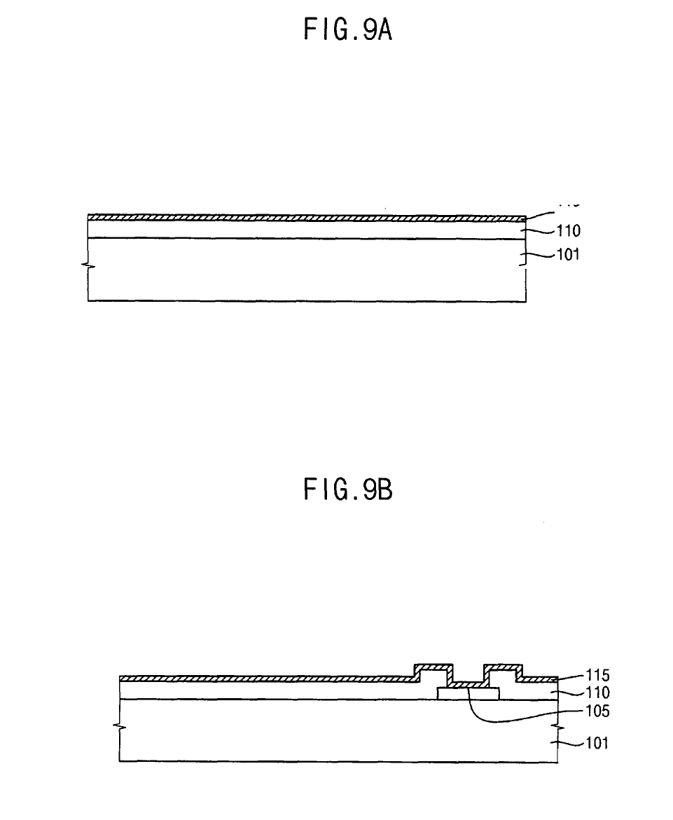

Referring to FIGS. 9A and 9B, a first conductive interlayer 115 is formed over the passivation layer 110, within the first opening 104′ and on the chip pad 105 as shown in FIGS. 9A and 9B. The first conductive interlayer 115 may include a barrier material layer and a seed layer overlying the barrier material layer. The barrier material layer may, for example, include a material such as titanium, copper or the like or an alloy thereof. The seed layer may, for example, include a material such as copper, aluminum, titanium, tungsten or the like or an alloy thereof. The seed layer may be a single layer or a multi-layer depending on specific applications. For example, the seed layer may include a copper layer and a titanium layer formed on the copper layer.

In one embodiment, the barrier material layer and the seed layer of the first conductive interlayer 115 may be formed using a sputtering technique. In another embodiment, the barrier material layer and the seed layer of the first conductive interlayer 115 may be sequentially stacked.

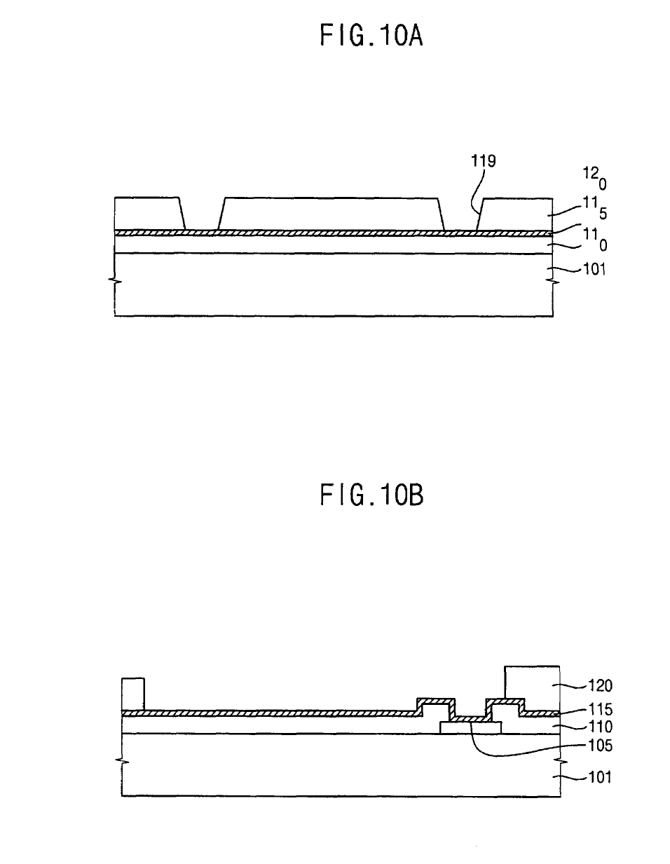

Next, a plurality of redistribution lines 135 (i.e., first redistribution lines) are formed on the passivation layer 110 to be connected to the chip pad 105. An exemplary process of forming the plurality of first redistribution lines 135 will be described with reference to FIGS. 10A to 12B.

As shown in FIGS. 10A and 10B, a mold pattern 120 is formed on the first conductive interlayer 115. In one embodiment, the mold pattern 120 may be formed by depositing a photosensitive material, e.g., a photoresist, over the first conductive interlayer 115 followed by exposure and developing processes to define a plurality of channels or grooves 119 exposing the first conductive interlayer 115. As exemplarily illustrated in FIG. 10A, sidewalls of the channels 119 defined in the mold pattern 120 may form obtuse angles with the upper surface of the first conductive interlayer 115. This process may be done by controlling the photolithography process conditions as is known to one skilled in the art. The examples of forming a mold pattern having obtuse angles are described in Korean Patent Application Publication Nos. 2005-0110735 and No. 2000-0066338, the contents of which are incorporated herein by reference. Therefore, the widths of the channels 119 are wider at the upper portion than the lower portion of the channels 119.

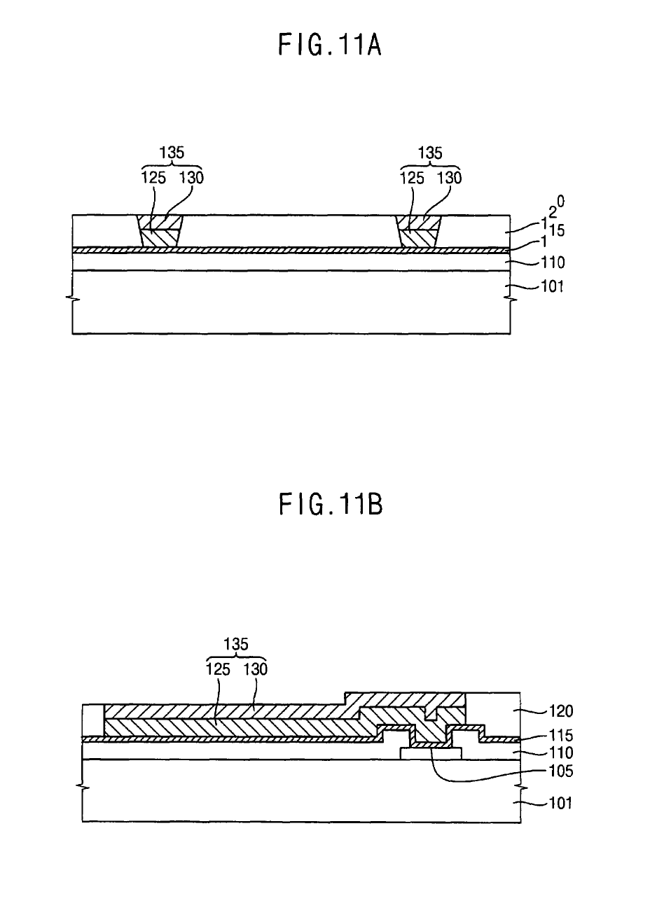

As shown in FIGS. 11A and 11B, first redistribution lines 135 are formed within the channels 119 defined in the mold pattern 120.

In one embodiment the first redistribution lines 135 may be formed using one or more plating processes. For example, a first lower conductive layer 125 may be plated within each channel 119 defined in the mold pattern 120 using portions of the first conductive interlayer 115 exposed by the channels 119 as a seed material. Subsequently, a first upper conductive layer 130 may be plated on each first lower conductive layer 125 using the first lower conductive layer 125 as a seed material. The first lower conductive layer 125 may, for example, include a material such as copper or the like or an alloy thereof. The first upper conductive layer 130 may, for example, include a material such as nickel or the like or an alloy thereof.

As the widths of the channels 119 are wider at the upper portion thereof, the widths of the resulting first redistribution lines formed (molded) within the channels 119 are therefore wider at the upper portion thereof. Therefore, the upper surface of the passivation layer 110 and the sidewalls of the first redistribution lines 135 form acute angles between them.

Alternatively, the first redistribution line 135 having a width greater at the upper portion than the lower portion thereof can be formed by thin film deposition and etching techniques using a suitable etchant that can selectively etch the bottom portion of the first redistribution line 135 to form a recess in the sidewall of the lower portion of the first redistribution line 135. In some embodiments, the first redistribution line 135 may include multiple layers, lower portions of which have a higher etch rate when exposed to a particular etchant.

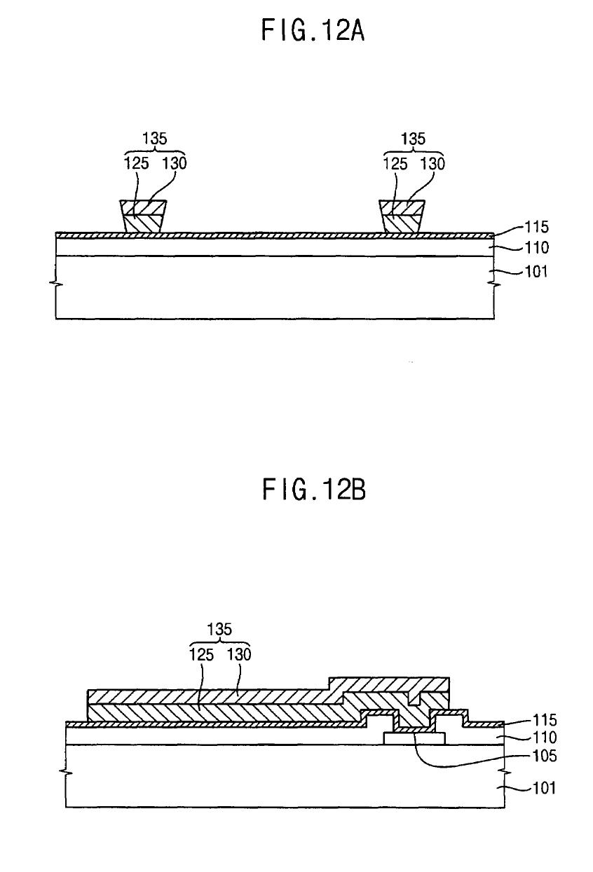

As shown in FIGS. 12A and 12B, the mold pattern 120 may be removed. In one embodiment, the mold pattern 120 may be removed using a process such as ashing, striping, or the like or a combination thereof. Upon removing the mold pattern 120, portions of the first conductive interlayer 115 are exposed by the first redistribution lines 135.

As exemplarily illustrated in FIG. 12A, sidewalls of the first redistribution layer patterns 135 may form acute angles with the upper surface of the first conductive interlayer 115.

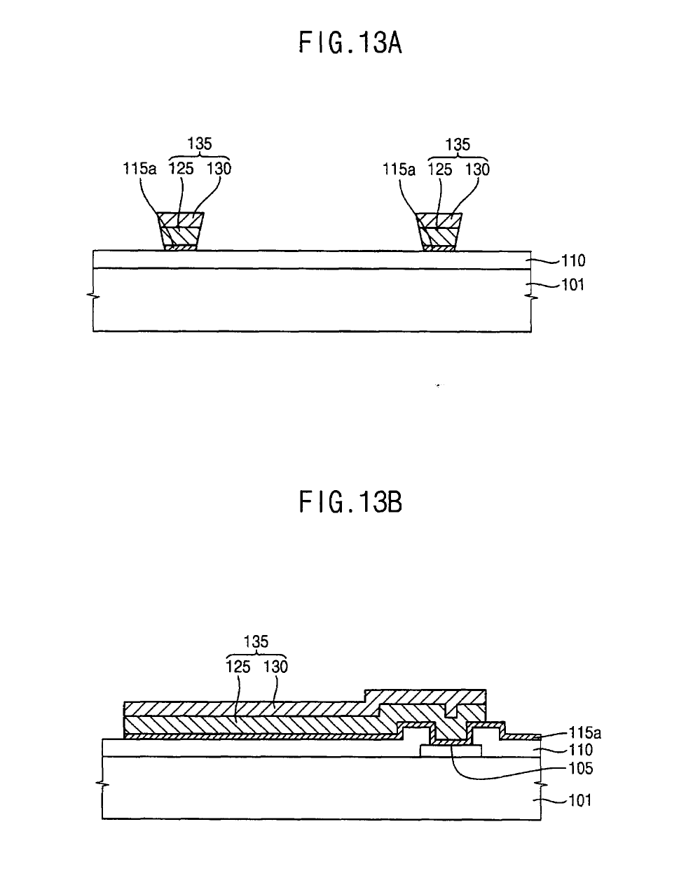

As shown in FIGS. 13A and 13B, portions of the first conductive interlayer 115 exposed by the first redistribution lines 135 are removed to form a first conductive interlayer pattern 115a. Accordingly, each first redistribution line 135 may include a first lower conductive pattern 125 and a first upper conductive pattern 130, which are sequentially stacked over the first conductive interlayer pattern 115a.

In one embodiment, the exposed portions of the first conductive interlayer 115 may be removed using a suitable etching process in which the portions of the first conductive interlayer 115 are etched selectively with respect to the first redistribution lines 135. In detail, an etchant used in the etching process to remove the exposed portions of the first conductive interlayer 115 may have a lower etch rate with respect to the first lower conductive pattern 125 than to the first conductive interlayer 115. Further, the etchant may have a lower etch rate with respect to the first upper conductive pattern 130 than to the first lower conductive pattern 125. As a result, during the etching process to remove the exposed portions of the first conductive interlayer 115, the sidewalls of the first redistribution lines 135 may also be partially removed more heavily at the bottom portion thereof. In this case, the acute angles defined between the upper surface of the passivation layer 110 and the sidewalls of the first redistribution lines 135 may be even smaller than those defined between the upper surface of the first conductive interlayer 115 and the sidewalls of the first redistribution lines 135.

As a result, edges of each of the first redistribution lines 135 are laterally recessed inward, for example, toward a midline of a corresponding first redistribution line 135. Thus, laterally recessed edges of a first conductive interlayer pattern 115a, a first lower conductive pattern 125, and a first upper conductive pattern 130 define a recess in a sidewall of the first redistribution line 135.

In one embodiment, the acute angle defined by the upper surface of the passivation layer 110 and the sidewalls of the first redistribution lines 135 may be in a range of about 30 degrees to about 75 degrees such that a void can be easily formed near or within the recess.

The recess is shown to have a triangle shape in cross-section. However, the recess may have a rectangle or similar shape in cross-section.

In another embodiment, a first lower conductive layer (not illustrated) to form the first lower conductive pattern 125 and a first upper conductive layer (not illustrated) to form the first upper conductive pattern 130 are sequentially formed over the passivation layer 110 using conventional deposition techniques. The first lower conductive pattern 125 may be comprised of a material capable of being etched selectively with respect to the first upper conductive pattern 130. In such an embodiment, recesses or undercuts may be defined in the sidewalls of the first redistribution lines 135 by etching the first lower conductive layer selectively with respect to the first upper conductive layer. In other words, the first lower conductive layer may be formed of a material such that it can be etched faster than the first upper conductive layer during an etching process to form the first lower conductive pattern 125 and the first upper conductive pattern 130. Also, this is true for a case where an additional etching process is performed after the first lower conductive pattern 125 and the first upper conductive pattern 130 are formed.

As a result, edges of each of the first lower conductive pattern 125 are laterally recessed inward toward a midline of a corresponding first redistribution line 135. Thus, a laterally recessed edge of the first lower conductive pattern 125 may define a recess in a sidewall of the first redistribution line 135. Also, according to another embodiment, a laterally recessed edge of the first lower conductive pattern 125 and the first upper conductive line 130 may collectively define a recess in a sidewall of the first redistribution line 135, at least portion of which may have an obtuse angle with respect to the upper surface of the passivation layer 110. Therefore, the width of the first upper conductive pattern 130 may be greater than that of the first lower conductive pattern 125.

Next, a first insulation layer 140a is formed over the lower structure 101 including the first redistribution lines 135 under conditions sufficient to ensure that voids 145 are contained within the first insulation layer 140a or formed adjacent to the first redistribution lines 135 to yield the structure exemplarily shown in FIG. 3A.

For example, the first insulation layer 140a may be formed by spin coating an insulating material over the lower structure 101 including the first redistribution lines 135. Alternatively, a tape including an organic material may be placed over the lower structure 101 to form the first insulation layer 140a. Also, an organic material having a suitable viscosity may be applied over the lower structure 101 using a squeezer or a dispenser. The insulating material may have a critical viscosity between about 250 CP and about 2000 CP. In one embodiment, the insulating material has a critical viscosity in a range from about 300 CP to about 2000 CP. Portions of the first insulation layer 140a on the passivation layer 110 (i.e., not on the first redistribution lines 135) may have a thickness between about 7 μm and about 10 μm. The insulating material may, for example, include a material such as SiNₓ, SiOₓ, resin, polyimide, or the like or a combination thereof. Inorganic materials such as resin or polyimide may be used to control the viscosity suitable to form the void 145 adjacent to a sidewall of the first redistribution lines 135, for example, in a recess defined in the sidewall of the first redistribution line 135.

In one embodiment, the first insulation layer 140a may be baked after being spin coated. For example, the first insulation layer 140a may be subject to a heat-treatment (hard bake) at a temperature of about 250° C. to about 350° C., more preferably, at about 280° C. to about 320° C., within about ten minutes after the spin coating process. As the first insulation layer 140a may be baked before the recess defined in the sidewall of the first redistribution lines 135 is substantially completely filled with the first insulation layer 140a, the void 145 can be formed adjacent to the sidewall of the first redistribution lines 135. The void 145 may be disposed within the recess and its outer circumference is defined by the sidewall of the first redistribution lines 135 and an outer surface of the first insulation layer 140a as illustrated in FIG. 3D. However, the void 145 may also be outside of the recess as shown in FIG. 3. Depending on specific applications, soft bake at a temperature of about 110° C. to about 120° C. may be performed before the hard bake discussed above. Therefore, by controlling the timing of the baking and the heat-treatment, the size and the location of the voids 145 can be controlled as illustrated in FIG. 3D. Also, the size of the voids 145 can be controlled by adjusting the size of the recess. For example, by increasing the size of the recess or undercuts, the size of the voids 145 can be increased, and vice versa. In some embodiments, the top of the void 145 may be located higher than that of the first redistribution line 135. In FIG. 3D, dotted lines illustrate the change in shape of the first insulation layer 140a after the first insulation layer 140a is spin coated before the first insulation layer 140a becomes solidified by heat treatment (“baking”).

The first insulation layer 140a may also be patterned to form an opening (i.e., a second opening 107) to expose a portion of the first redistribution line 135, thereby forming a redistributed bond pad 106 as exemplarily shown in FIG. 3B. Although only one second opening 107 is shown, it will be appreciated that more than one second opening 107 may be formed to expose a plurality of first redistribution lines 135, thereby forming a plurality of redistributed bond pads 106.

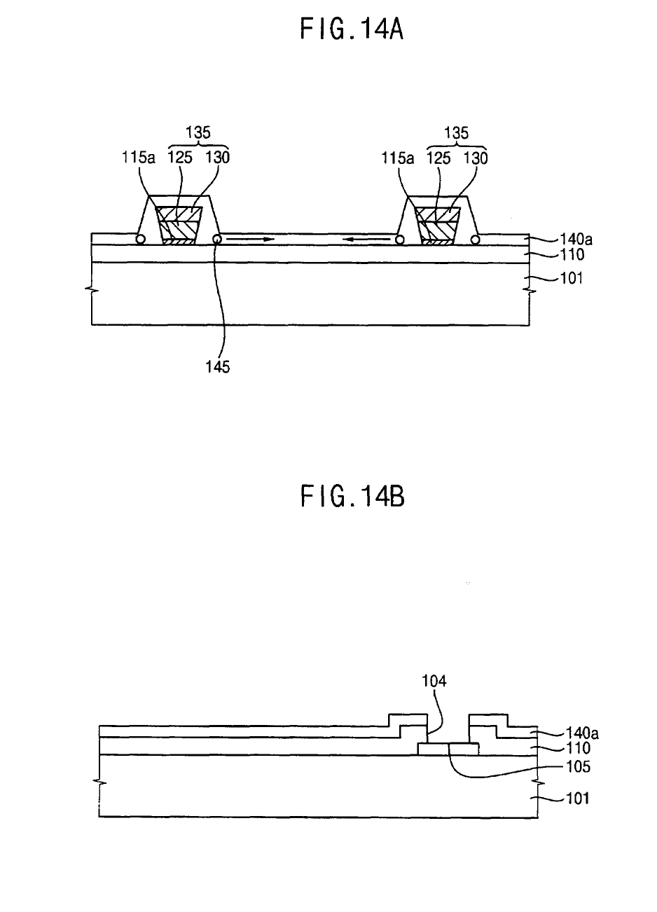

FIG. 14A is a cross-sectional view of an exemplary method of forming one embodiment of the semiconductor device shown in FIG. 4, taken along lines IVA-IVA′. FIG. 14B is a cross-sectional view of an exemplary method of forming one embodiment of the semiconductor device shown in FIG. 4, taken along lines IVB-IVB′.

In one embodiment, the semiconductor device described with respect to FIGS. 4, 5A and 5B may be formed using a process similar to that described above with respect to FIGS. 3A, 3B and 8A to 13B to yield a preliminary structure shown in FIG. 14A.

As shown in FIGS. 14A and 14B, the first opening 104 may be formed by patterning the first insulation layer 140a and the passivation layer 110 to expose at least a portion of the chip pad 105. Although only one first opening 104 and one chip pad 105 are shown, it will be appreciated that any number of first openings and chip pads 105 may be formed.

In one embodiment, the first opening 104 may be formed by sequentially patterning the first insulation layer 140a and the passivation layer 110 (e.g., in the same process). In another embodiment, however, a preliminary opening that exposes at least a portion of the chip pad 105 may be formed within the passivation layer 110 before the first insulation layer 140a is formed. In such an embodiment, the first insulation layer 110 may be formed over the passivation layer 110 and within the preliminary opening and the first opening may then be defined within the first insulation layer 140a to expose at least a portion of the chip pad 105.

Referring back to FIG. 14A, the first insulation layer 140a with the voids 145 may be initially formed to have preliminary voids 145 adjacent the first redistribution lines 135a overlying the passivation layer 110 in accordance with an exemplary process described with respect to FIG. 3A and FIG. 3D. The first insulation layer 140a may then be subjected to additional heat treatment to form an enlarged void 145a from the preliminary voids 145. Upon subjecting the first insulation layer 140a to additional heat treatment, the voids 145 contained within (or defined by) the first insulation layer 140a begin to move toward a central region between adjacent ones of first redistribution lines 135. Such movement is conceptually shown at the inwardly pointing arrows. The heat treatment may be performed by heating the first insulation layer 140a at a temperature between about 100° C. and about 600° C. for about 10 min. to about 120 min. according to one embodiment. More preferably, the heat treatment may be performed at a temperature between about 100° C. and about 300° C. for about 10 min. to about 120 min.

Upon subjecting the first insulation layer 140a with the void 145 as shown in FIG. 14A to the heat treatment exemplarily described above, the voids 145 present between adjacent ones of the first redistribution lines 135 coalesce into the enlarged void 145a as exemplarily shown in FIGS. 5A and 5B. The voids 145 may extend or expand horizontally until they contact each other to form the enlarged void 145a. For this reason, preferably, the voids 145 initially formed may be close enough to each other such that they can be coalesced into the enlarged void 145a during the heat treatment. In one aspect of the present invention, the enlarged void 145a may be spaced apart from the upper surface of the passivation layer 110 as shown in FIGS. 5A and 5B. Alternatively, although not shown, the enlarged void 145a may be in contact with the upper surface with the passivation layer 110. For example, as shown in FIG. 7D, the enlarged void 145a may have an arch shape in cross-section view, of which a bottom surface is in contact with the upper surface of the passivation layer 110.

Applicant of the present invention has discovered that if the first insulation layer 140a is heat treated under about 100° C., the voids 145 may not expand or extend enough to form the enlarged void 145a. On the other hand, if the first insulation layer 140a is heated over 600° C., undesirable thermal stress can be applied to the first redistribution line or to the devices such as transistors, resistors, diode, capacitors, signal lines, contact structure included in the lower structure 101, degrading the characteristics of the resulting electronic products.

Applicant of the present invention has also discovered that if the first insulation layer 140a is heat treated less than about 10 min., the voids 145 may not expand or extend enough to form the enlarged void 145a. On the other hand, if the first insulation layer 140a is heat treated longer than 120 min., undesirable physical stress can be applied to the first redistribution line or to the devices such as transistors, resistors, diode, capacitors, signal lines, contact structure included in the lower structure 101, also degrading the characteristics of the resulting electronic products.

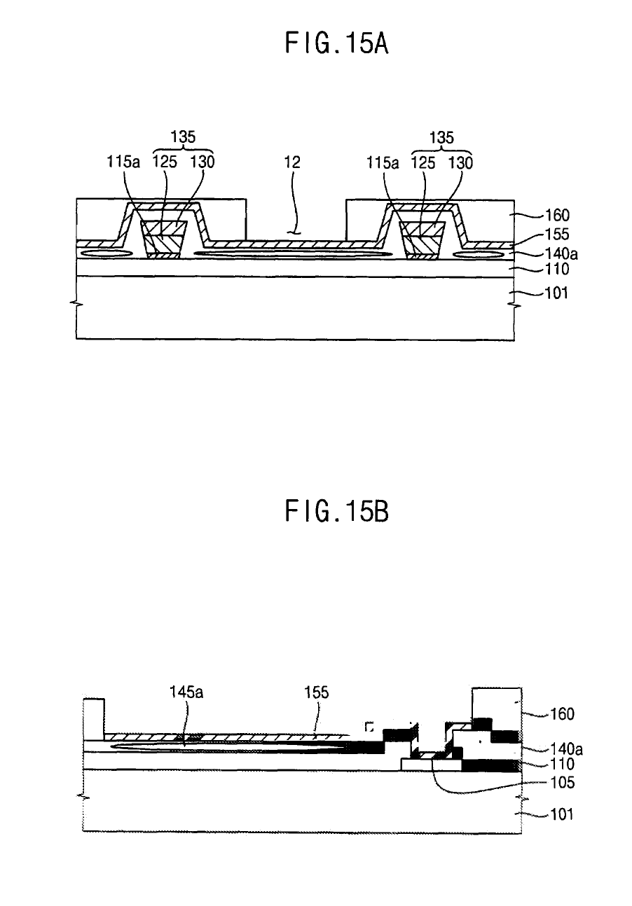

FIGS. 15A, 16A, and 17A are cross-sectional views of an exemplary method of forming one embodiment of the semiconductor device shown in FIG. 6, taken along lines VIA-VIA′. FIGS. 15B, 16B, and 17B are cross-sectional views of an exemplary method of forming one embodiment of the semiconductor device shown in FIG. 6, taken along lines VIB-VIB′.

In one embodiment, the semiconductor device described with respect to FIGS. 6, 7A and 7B may be formed according to a process similar to that exemplarily described with respect to FIGS. 5A, 5B, 14A, and 14B. According to the present embodiment, however, another redistribution line 175 (i.e., a second redistribution line) may be additionally formed on the first insulation layer 140a so as to be located over the enlarged void 145a. Although only one second redistribution line 175 is shown, it will be appreciated that more than one second redistribution line 175 may be formed.

As shown in FIGS. 15A and 15B, a second conductive interlayer 155 may be formed over the first insulation layer 140a so as to be located over the enlarged void 145a. The second conductive interlayer 155 may include a barrier material layer and a seed layer overlying the barrier metal layer. The barrier material layer may, for example, include a material such as titanium, chromium, or the like or an alloy thereof. The seed layer may include a material, for example, copper or the like or an alloy thereof. In one embodiment the barrier material layer and the seed layer of the second conductive interlayer 155 may be formed using a sputtering technique. In another embodiment the barrier material layer and the seed layer of the second conductive interlayer 155 may be sequentially stacked.

Next, a second mold pattern 160 is formed on the second conductive interlayer 155. In one embodiment, the second mold pattern 160 may be formed by depositing a photosensitive material, e.g., a photoresist, over the second conductive interlayer 155 followed by exposure and developing processes to form a channel or groove 12 exposing a portion of the second conductive interlayer 155. The channel 12 may expose a portion of the second conductive interlayer 155 located over the enlarged void 145a.

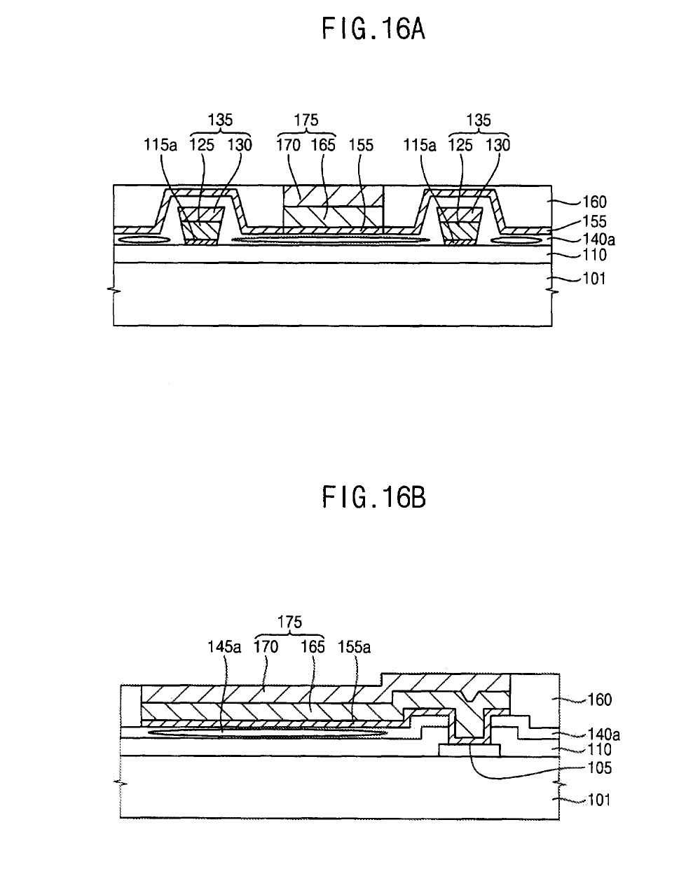

Referring to FIGS. 16A and 16B, the second redistribution line 175 may then be formed within the channel 12 of the second mold pattern 160. In one embodiment, the second redistribution line 175 may be formed using one or more plating processes. For example, a second lower conductive layer 165 may be plated using portions of the second conductive interlayer 155 exposed by the grooves as a seed material. Subsequently, a second upper conductive layer 170 may be plated using the second lower conductive layer 165 as a seed material. The second lower conductive layer 165 may, for example, include a material such as copper or the like or an alloy thereof. The first upper conductive layer 170 may, for example, include a material such as nickel or the like or an alloy thereof.

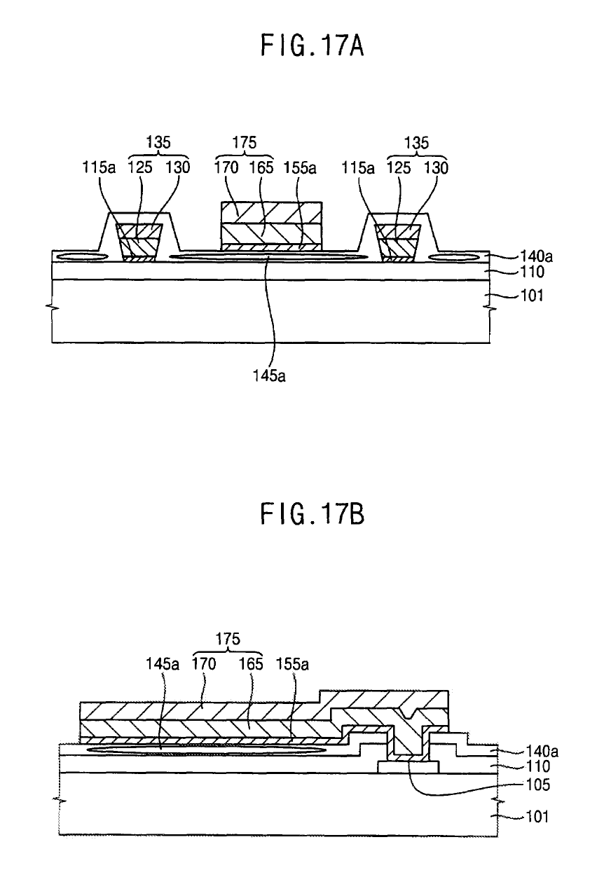

As shown in FIGS. 17A and 17B, the second mold pattern 160 may be removed. In one embodiment, the second mold pattern 160 may be removed in a process such as ashing, striping, or the like or a combination thereof. Upon removing the second mold pattern 160, portions of the second conductive interlayer 155 are exposed by the second redistribution line 175. Subsequently, portions of the second conductive interlayer 155 that are exposed by the second redistribution line 175 are removed. In one embodiment, the exposed portions of the second conductive interlayer 155 may be removed by etching the second conductive interlayer 155 to form a second conductive interlayer pattern 155a.

Next a second insulation layer 140b is formed over the lower structure 101 including the second redistribution line 175 to yield the structure exemplarily shown in FIG. 7A. In one embodiment, the second insulation layer 140b may be formed by conventional thin film deposition techniques, for example, spin coating an insulating material over the lower structure 101. In one embodiment, the insulating material may, for example, include SiNₓ, SiOₓ, resin, polyimide, or the like or a combination thereof.

The second insulation layer 140b may also be patterned to form an opening (i.e., a third opening) exposing a portion of the second redistribution line 175, thereby forming a redistributed bond pad 106 as exemplarily shown in FIG. 7B. In one embodiment, the second insulation layer 140b may be formed by subjecting the second insulation layer 140b to exposure and developing processes.

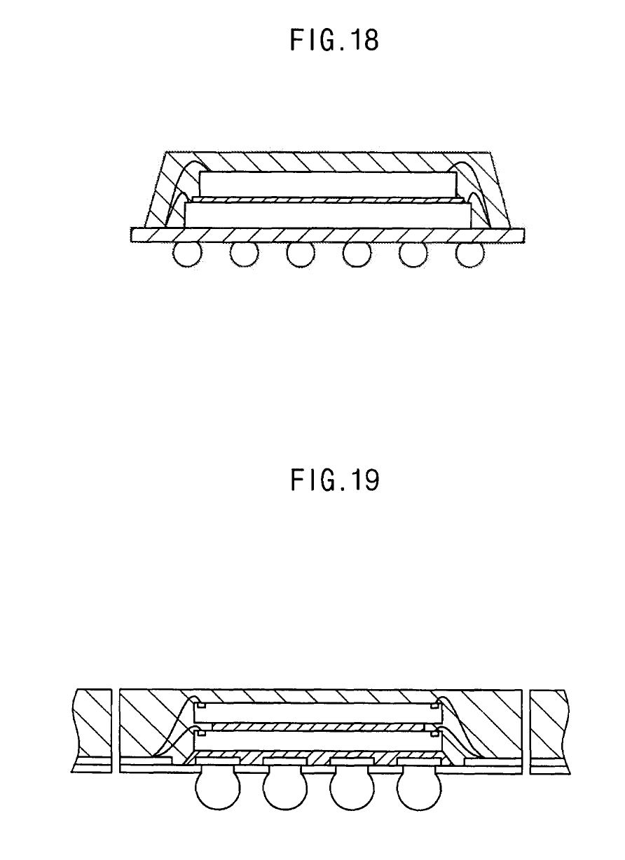

FIGS. 18 to 20 illustrate implementations of the semiconductor devices shown in FIGS. 2, 4 and 6, according to some embodiments.

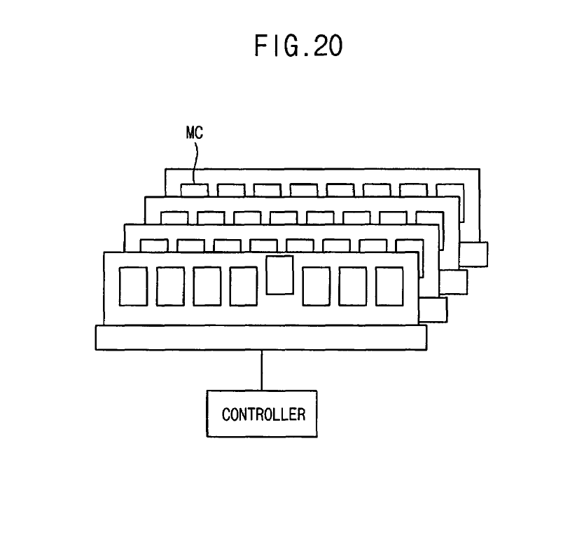

Referring to FIGS. 18 to 20, it will be appreciated that the semiconductor devices exemplarily described above may be incorporated within any device using a wafer level fabricated package structure. For example, the semiconductor devices exemplarily described above may be incorporated within a stack package system (see FIG. 18), within a multi-chip package system (see FIG. 19) or within a module (see FIG. 20). In these embodiments, some or all of the chips include void structures discussed above.

Also, the present application has been described in connection with distribution lines. However, one skilled in the art will appreciate that embodiments of the present invention may also be applied to other conductive structures besides the redistribution lines in a semiconductor device to reduce parasitic capacitance therebetween.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Various operations will be described as multiple discrete steps performed in a manner that is most helpful in understanding the invention. However, the order in which the steps are described does not imply that the operations are order-dependent or that the order that steps are performed must be the order in which the steps are presented.

While embodiments of the present invention have been particularly shown and described above, it will be understood by those of ordinary skill in the art that various changes in form and details may be made therein without departing from the spirit and scope of the present invention as defined by the following claims.

What is claimed is:

1. A semiconductor device, comprising:
a lower structure formed on a semiconductor structure, the lower structure having chip pads;
a passivation layer located over the chip pads, the passivation layer comprising first openings defined therein that expose at least a portion of the chip pads;
at least two adjacent redistribution lines spaced apart from each other and located over the passivation layer, the at least two adjacent redistribution lines respectively coupled to the chip pads through corresponding ones of the first openings; and
an insulation layer located over the passivation layer, wherein the insulation layer includes a void extending between the at least two adjacent redistribution lines.

2. The semiconductor device of claim 1, wherein the void overlies the passivation layer.

3. The semiconductor device of claim 1, wherein an upper portion of the at least two adjacent redistribution lines is wider than a lower portion thereof.

4. The semiconductor device of claim 1, wherein an acute angle is defined between a sidewall of the at least two adjacent redistribution lines and an upper surface of the passivation layer.

5. The semiconductor device of claim 4, wherein the acute angle is defined in a range of about 30 degrees to about 75 degrees.

6. The semiconductor device of claim 1, wherein the at least two adjacent redistribution lines has a recess defined in a sidewall thereof, the void being located within at least a portion of the recess.

7. The semiconductor device of claim 1, wherein the void contacts a sidewall of the at least two adjacent redistribution lines such that at least a portion of the sidewall of the at least two adjacent redistribution lines is exposed to an interior of the void.

8. The semiconductor device of claim 1, wherein a top of the void is higher than a top surface of the at least two adjacent redistribution lines.

9. The semiconductor device of claim 1, wherein the void has a triangle shape, an oval shape, an arch shape in cross section view.

10. The semiconductor device of claim 1, wherein the void extends along a length of the at least two adjacent redistribution lines.

11. The semiconductor device of claim 1, wherein the insulation layer contains one or more voids between the at least two adjacent redistribution lines.

12. The semiconductor device of claim 1, wherein the void contacts opposite sidewalls of the at least two adjacent first redistribution lines.

13. The semiconductor device of claim 1, further comprising another redistribution line disposed over the insulation layer, another redistribution line directly overlying the void.

14. A semiconductor device, comprising:
at least two adjacent conductive lines spaced apart from each other over a semiconductor substrate; and
an insulation layer between the at least two adjacent conductive lines, wherein the insulation layer includes a void between the at least two adjacent conductive lines,
wherein a recess is defined in a sidewall of the at least two adjacent conductive lines and, wherein the void is disposed within at least a portion of the recess.

15. The semiconductor device of claim 14, further comprising a passivation layer over the semiconductor substrate, wherein the void is disposed over the passivation layer between the at least two adjacent conductive lines.

16. The semiconductor device of claim 14, wherein an upper portion of the at least two adjacent conductive lines is wider than a lower portion thereof,

17. A method of forming a semiconductor device, the method comprising:
forming a lower structure having chip pads formed on a semiconductor substrate;
forming a passivation layer over the chip pads, the passivation layer comprising openings defined therein to expose at least a portion of corresponding ones of the chip pads;
forming at least two adjacent first redistribution lines over the passivation layer, wherein the at least two first redistribution lines are respectfully coupled to the corresponding chip pads through corresponding ones of the openings; and
forming an insulation layer overlying the at least two adjacent first redistribution lines and over the passivation layer,
wherein the insulation layer includes a void extending between the at least two adjacent first redistribution lines.

18. The method of claim 17, wherein a recess is formed in a sidewall of the at least two adjacent first redistribution lines.

19. The method of claim 18, wherein forming the insulation layer comprises:
applying an insulating material over the passivation layer and adjacent to the sidewall of the at least two adjacent first redistribution lines; and
heat treating the insulating material such that the void is defined by the sidewall of the at least two adjacent first redistribution lines and an outer surface of the insulation layer, before the recess is substantially completely filled by the insulating material.

20. The method of claim 19, wherein applying the insulating material comprises spin coating, applying a tape including an organic material, or using a squeezer.

21. The method of claim 19, wherein the insulating material has a viscosity of about 250 CP to about 2000 CP.

22. The method of claim 19, wherein the heat treating is performed at a temperature range of about 250° C. to about 350° C. within about ten minutes after applying the insulating material.

23. The method of claim 17, wherein the insulation layer is formed to include at least two voids between the at least two adjacent first redistribution lines, further comprising heat treating the resulting structure at a temperature range of about 100° C. to 600° C. for about 10 min. to about 120 min. such that the at least two voids coalesce into an enlarged void extending between the at least two adjacent redistribution lines.

24. The method of claim 23, further comprising forming a second redistribution line directly overlying the enlarged void.

25. The method of claim 17, wherein an acute angle is defined between a sidewall of the at least two adjacent first redistribution lines and an upper surface of the passivation layer.
